(19) United States
(12) Patent Application Publication
(10) Pub. No.: US 2015/0076670 A1
(43) Pub. Date: Mar. 19, 2015

(54) CHIP PACKAGE STRUCTURE AND MANUFACTURING METHOD THEREOF

(71) Applicant: ChipMOS Technologies Inc., Hsinchu (TW)

(72) Inventors: Yu-Tang Pan, Hsinchu (TW); Shih-Wen Chou, Hsinchu (TW)

(73) Assignee: ChipMOS Technologies Inc., Hsinchu (TW)

(21) Appl. No.: 14/255,973

(22) Filed: Apr. 18, 2014

(30) Foreign Application Priority Data
Sep. 17, 2013 (TW) 102133720

(51) Int. Cl. H01L 23/31; H01L 23/373; H01L 21/56; H01L 23/00; H01L 23/552; H01L 23/433

(52) U.S. Cl. CPC H01L 23/3157; H01L 23/552; H01L 23/4334; H01L 21/56; H01L 24/83; H01L 24/48; H01L 23/3736; H01L 2924/01079; H01L 2924/01029; H01L 2924/01047; H01L 2924/01013; H01L 2924/01046; H01L 2224/8385; H01L 2224/48227; H01L 2224/48091; H01L 2224/485
USPC 257/659; 438/118

(57) ABSTRACT

A chip package structure and a manufacturing method thereof are provided. The chip package structure includes a substrate, a chip, a plurality of wires, a film layer, a carrier, and an encapsulant. The substrate has an upper surface and a lower surface. The chip is mounted on the upper surface of the substrate. The wires are electrically connected to the chip and the substrate respectively. The film layer is attached to the substrate and entirely encapsulates the chip and the wires. The carrier is adhered on the film layer. The encapsulant is disposed on the upper surface of the substrate, wherein the encapsulant has an electro-magnetic shielding filler. The encapsulant at least partially encapsulates the carrier and the film layer, and the encapsulant covers the chip and the wires.

### CROSS-REFERENCE TO RELATED APPLICATION

This application claims the priority benefit of Taiwan application serial no. 102133720, filed on Sep. 17, 2013. The entirety of the above-mentioned patent application is hereby incorporated by reference herein and made a part of this specification.

### BACKGROUND

1. Technical Field

The invention relates to a package structure and a manufacturing method thereof. Particularly, the invention relates to a chip package structure and a manufacturing method thereof.

2. Related Art

As electronic products are continually developed towards a trend of small size, multi-function and high performance, integrated circuit (IC) chips are also required to meet the requirements of miniaturization, high density, high power and high speed, so that a condition of electronic signals being influenced by electro-magnetic interference (EMI) is getting severer. In order to prevent the EMI from influencing the stability of the IC chip during operation, conventionally a metal cover is used to shield the chip, so as to prevent the leakage of electro-magnetic waves and the entering of electro-magnetic interference from outside. Metal conductors are materials suitable for blocking the EMI, but the metal materials are heavy, uneasy to be shaped and in high price, hence they cannot satisfy the requirement of miniaturization and mass production in low cost. Therefore, a polymer material which are lightweight, easy to be shaped and in low price almost replaces the metal materials as a protection element for the IC chips. However, the polymer material which is non-conductive is unable to achieve the electro-magnetic interference shielding effect.

### SUMMARY

The invention is directed to a chip package structure and a manufacturing method thereof, which have a high assembly yield, a low manufacturing cost and are good at electro-magnetic interference (EMI) shielding.

The invention provides a chip package structure including a substrate, a chip, a plurality of wires, a film layer, a carrier, and an encapsulant. The substrate has an upper surface and a lower surface. The chip is mounted on the upper surface of the substrate. The wires are electrically connected to the chip and the substrate respectively. The film layer is disposed on the substrate in a covering and attaching manner and entirely encapsulates the chip and the wires. The carrier is adhered on the film layer. The encapsulant is disposed on the upper surface of the substrate. The encapsulant has an electro-magnetic shielding filler. In addition, the encapsulant at least partially encapsulates the carrier and the film layer, and the encapsulant covers the chip and the wires.

The invention provides a manufacturing method of a chip package structure including following steps. First, a substrate is provided, where the substrate has an upper surface and a lower surface. Then, a chip is mounted on the upper surface of the substrate. Thereafter, a plurality of wires are formed, where the wires are electrically connected to the chip and the substrate respectively. Then, a film layer is disposed on the substrate in a covering and attaching manner, where a carrier is adhered on the film layer, and the film layer entirely encapsulates the chip and the wires. Then, an encapsulant is formed on the upper surface of the substrate, wherein the encapsulant has an electro-magnetic shielding filler. In addition, the encapsulant at least partially encapsulates the carrier and the film layer, and the encapsulant covers the chip and the wires.

In an embodiment of the invention, the carrier includes a flexible insulating film or a metal plate.

In an embodiment of the invention, the chip package structure further includes a plurality of external terminals. The external terminals are disposed on the lower surface of the substrate, and are electrically connected to the substrate.

In an embodiment of the invention, the film layer is a film-over-wire (FOW), and the film layer presents a semi-solid gel state when the film layer encapsulates the chip and the wires, such that the film layer has no interference on the wires.

In an embodiment of the invention, a material of the electro-magnetic shielding filler is selected from a group consisting of Ag, Fe, ferrite, Cu, Cu/Ni, Cu/Ag, Au, Al, Ni, brass, stainless steel, graphite, carbon black, carbon nanotube, carbon nanocapsule, carbon fiber, nickel-plated graphite, nickel-plated carbon fiber and copper/nickel-plated carbon fiber.

In an embodiment of the invention, the encapsulant further includes a heat dissipation filler.

In an embodiment of the invention, a material of the heat dissipation filler is selected from a group consisting of Ag, Fe, ferrite, Cu, Cu/Ni, Cu/Ag, Au, Al, Ni, Mg, brass, stainless steel, graphite, carbon black, carbon nanotube, carbon nanocapsule, carbon fiber, nickel-plated graphite, nickel-plated carbon fiber, copper/nickel-plated carbon fiber, Al₂O₃, MgO, BeO, SiO₂, ZnO, NiO, MN, Si₃N₄ and BN.

According to the above descriptions, since the chip and the wires are entirely encapsulated by the film layer first, and then further covered by the encapsulant having the electro-magnetic shielding filler, the packaged chip not only can effectively block the influence of the EMI through the encapsulant, but can also prevent the electrical contact between the chip and the electro-magnetic shielding filler by encapsulating the chip through the film layer.

In detail, the film layer is, for example, a film-over-wire (FOW), which presents a semi-solid gel state when the film layer encapsulates the chip and the wires, such that the wires may easily penetrate into the film layer without being interfered by the film layer, which may lead to wire breaking or damage. Besides, the film layer provides a certain degree of support after entirely encapsulating the chip and the wires, and would not slump to cause a contact between the wires and the carrier or the encapsulant, so as to avoid damage, shift, miscontact of the wires which may influence the electrical transmission function thereof. As the encapsulant has the electro-magnetic shielding filler, false operation or malfunction of the chip due to the external EMI can be effectively avoided.

On the other hand, the electro-magnetic shielding filler in the encapsulant which is a conductive material generally has the heat conductive effect, or a heat dissipation filler made of other materials can also be added in the encapsulant. Therefore, the chip package structure of the invention not only has better anti-EMI ability, but can also effectively conduct the heat generated during the operation of the chip to outside, so as to maintain or improve the performance of the chip.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A-FIG. 1E are schematic diagrams of a packaging process of a chip package structure according to an embodiment of the invention.

FIG. 2 and FIG. 3 are chip package structures of other possible embodiments of the invention.

### DETAILED DESCRIPTION OF DISCLOSED EMBODIMENTS

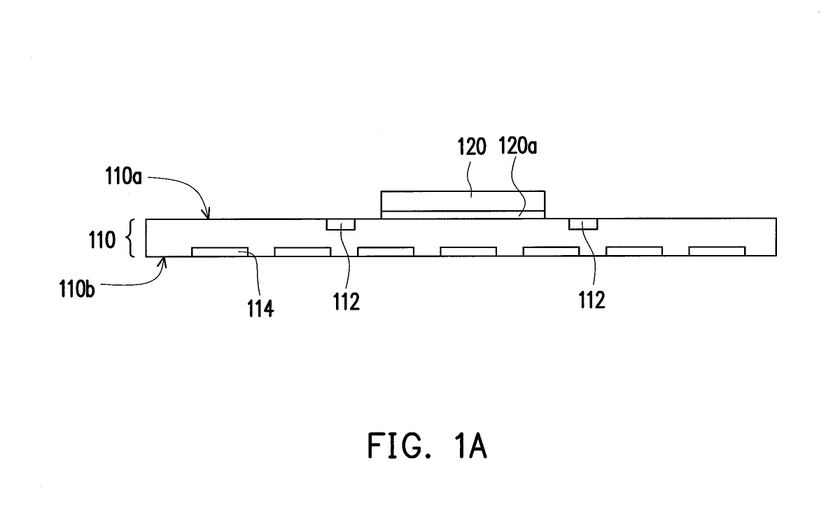

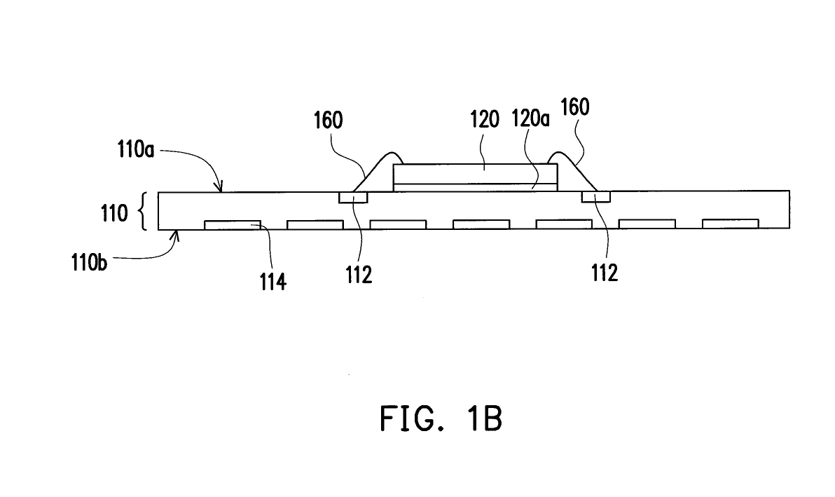

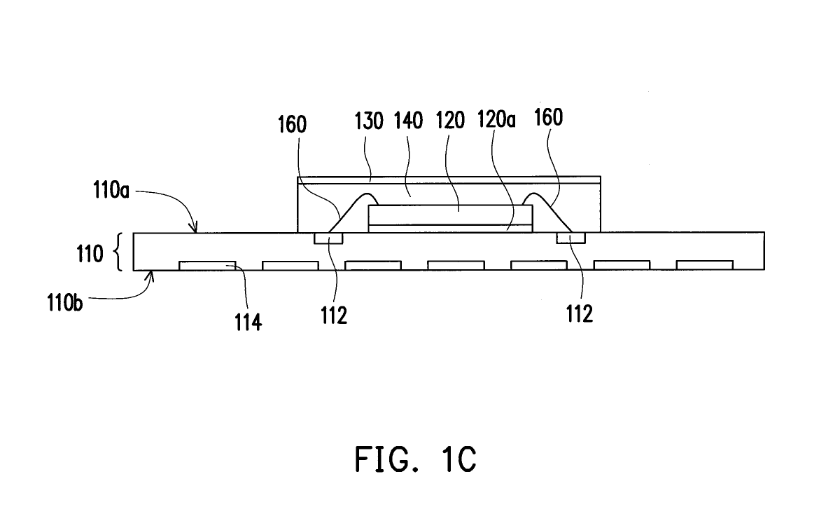

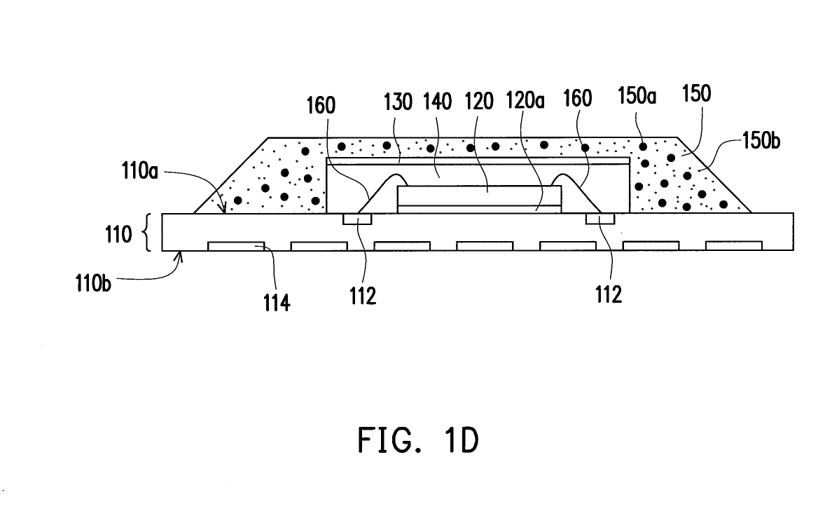

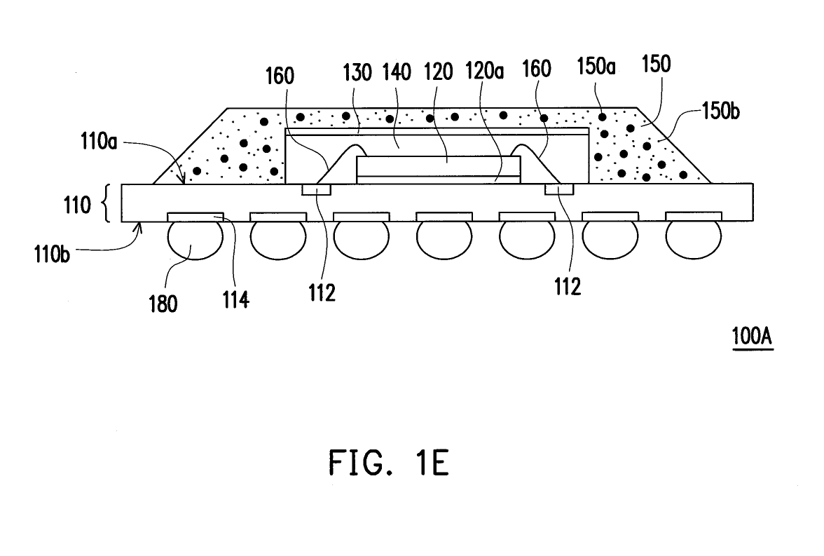

FIG. 1A-FIG. 1E are schematic diagrams of a packaging process of a chip package structure according to an embodiment of the invention. Referring to FIG. 1A, a substrate 110 is first provided, where the substrate 110 has an upper surface 110a and a lower surface 110b, and a chip 120 is mounted on the upper surface 110a of the substrate 110. In detail, the chip 120 is, for example, adhered to the upper surface 110a of the substrate 110 through an adhesive layer 120a. In the present embodiment, the substrate 110 is, for example, a multi-layer substrate fabricated according to a FR-4 substrate lamination technique or a ceramic substrate lamination technique, and the substrate 110 includes a plurality of pads 112 on the upper surface 110a of the substrate 110 and a plurality of pads 114 on the lower surface 110b of the substrate 110. On the other hand, the chip 120 can be an integrated circuit (IC) chip, for example, a graphics chip, a memory chip, a semiconductor chip or a driving chip, etc.

Then, referring to FIG. 1B, a plurality of wires 160 are formed to electrically connect the substrate 110 and the chip 120 according to a wire bonding technique. In detail, the chip 120 is electrically connected to the substrate 110 by the wires 160 connecting the pads 112, where the wires 160 can be made of a conductive metal material such as gold, copper, silver, palladium, aluminium or any alloy thereof, etc.

Then, referring to FIG. 1C, a film layer 140 is disposed on the substrate 110 in a covering and attaching manner, where a carrier 130 is adhered on the film layer 140, and the film layer 140 entirely encapsulates the chip 120 and the wires 160. Generally, the carrier 130 is, for example, a flexible insulating film or a metal plate which can provide a carrying function. Taking the metal plate as the carrier 130 can provide an electro-magnetic shielding effect and a heat dissipation effect, such that the chip 120 can maintain a normal operation function without being influenced by electro-magnetic interference (EMI), and the heat generated during the operation of the chip 120 can be effectively conducted to outside, so as to maintain the performance of the chip 120.

In the present embodiment, the film layer 140 is, for example, a film-over-wire (FOW), and presents a semi-solid gel state when the film layer 140 encapsulates the chip 120 and the wires 160, so that the film layer 140 has no interference on the wires 160. Therefore, when the carrier 130 configured with the film layer 140 is disposed on the substrate 110, the wires 160 can easily penetrate into the semi-solid gel state film layer 140 without being interfered by the film layer 140, which may lead to breaking or damage of the wires 160. Besides, the film layer 140 provides a certain degree of support after entirely encapsulating the chip 120 and the wires 160, and would not slump to cause a contact between the wires 160 and the carrier 130, so as to avoid damage, shift, miscontact of the wires 160 which may influence the electrical transmission function thereof.

Then, referring to FIG. 1D, an encapsulant 150 is formed on the upper surface 110a of the substrate 110 to at least partially encapsulate the carrier 130 and the film layer 140 and to cover the chip 120 and the wires 160, where the encapsulant 150 has an electro-magnetic shielding filler 150a. In the present embodiment, the encapsulant 150 entirely covers the carrier 130, the film layer 140, the chip 120 and the wires 160. Generally, the encapsulant 150 is made of epoxy or other polymer materials, and the electro-magnetic shielding filler 150a in the encapsulant 150 is a conductive material such as metal sheets, metal particles, metal fibers, non-metal particles, non-metal fibers, etc. In detail, the material of the electro-magnetic shielding filler 150a is selected from a group consisting of Ag, Fe, ferrite, Cu, Cu/Ni, Cu/Ag, Au, Al, Ni, brass, stainless steel, graphite, carbon black, carbon nanotube, carbon nanocapsule, carbon fiber, nickel-plated graphite, nickel-plated carbon fiber and copper/nickel-plated carbon fiber.

Moreover, the encapsulant 150 further includes a heat dissipation filler 150b, where materials of the heat dissipation filler 150b and the electro-magnetic shielding filler 150a can be the same or different. In detail, the material of the heat dissipation filler 150b is selected from a group consisting of Ag, Fe, ferrite, Cu, Cu/Ni, Cu/Ag, Au, Al, Ni, brass, stainless steel, graphite, carbon black, carbon nanotube, carbon nanocapsule, carbon fiber, nickel-plated graphite, nickel-plated carbon fiber, copper/nickel-plated carbon fiber, Mg, Al₂O₃, MgO, BeO, SiO₂, ZnO, NiO, AlN, Si₃N₄ and BN. Namely, the chip package structure of the invention not only has better anti-EMI ability, but can also effectively conduct the heat generated during the operation of the chip to outside, so as to maintain or improve the performance of the chip.

Finally, referring to FIG. 1E, after the encapsulant 150 is formed, a plurality of external terminals 180 are formed on the substrate 110, where the external terminals 180 are, for example, solder balls. In detail, the external terminals 180 are, for example, arranged on the lower surface 110b of the substrate 110 in an array, and are bonded to the pads 114 on the lower surface 110b for electrically connecting the substrate 110. Up to this point, manufacturing of the chip package structure 100A is approximately completed.

In view of the structure, referring to FIG. 1 E, the chip package structure 100A includes the substrate 110, the chip 120, the carrier 130, the film layer 140 and the encapsulant 150. The substrate 110 has the upper surface 110a and the lower surface 110b. The chip 120 is mounted on the upper surface 110a of the substrate 110 and is adhered to the substrate 110 through the adhesive layer 120a. The wires 160 electrically connect the chip 120 and the substrate 110. The film layer 140 attached to the carrier 130 is disposed on the substrate 110, and the film layer 140 entirely encapsulates the chip 120 and the wires 160, where the film layer 140 provides a certain degree of support after entirely encapsulating the chip 120 and the wires 160, and would not slump to cause a contact between the wires 160 and the carrier 130. The encapsulant 150 is disposed on the upper surface 110a of the substrate 110, and at least partially encapsulates the carrier 130 and the film layer 140, and covers the chip 120 and the wires 160, where the encapsulant 150 has the electro-magnetic shielding filler 150a. The chip package structure 100A further includes a plurality of external terminals 180, where the external terminals 180 are disposed on the lower surface 110b of the substrate 110, and are bonded to the pads 114 on the lower surface 110b for electrically connecting the substrate 110.

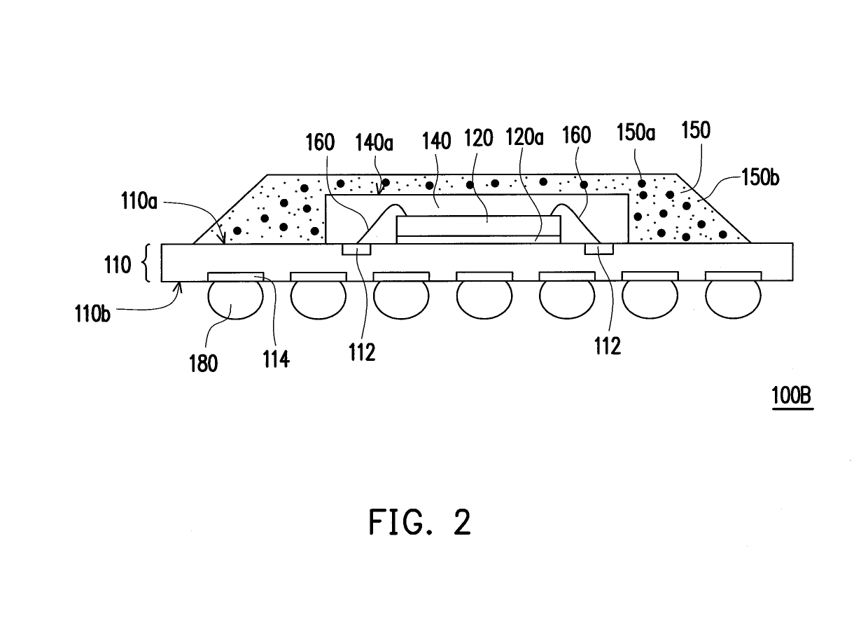

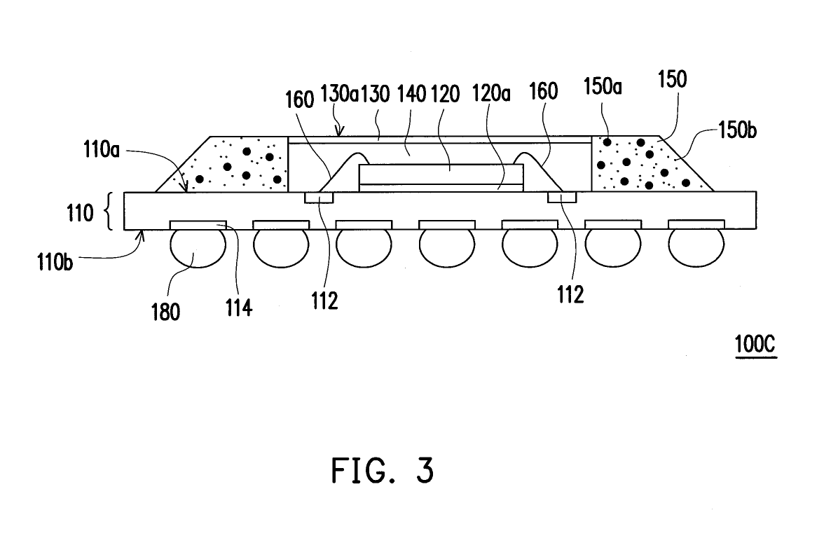

FIG. 2 and FIG. 3 are chip package structures of other possible embodiments of the invention. Referring to FIG. 2, the chip package structure 100B of FIG. 2 is similar to the chip package structure 100A of FIG. 1E, but a difference there between is that in the present embodiment, the chip package structure 100B does not contain the carrier 130. Namely, the encapsulant 150 directly contacts an upper surface 140a of the film layer 140 and entirely covers the film layer 140. Under such configuration, the chip package structure 100B may also have the same technical effects as that described in the aforementioned embodiment.

In view of a manufacturing process, the carrier 130 is removed after the film layer 140 is formed on the substrate 110, where the film layer 140 provides a certain degree of support after entirely encapsulating the chip 120 and the wires 160. Namely, in the follow-up manufacturing process, i.e. when the encapsulant 150 is formed on the upper surface 110a of the substrate 110 and encapsulates the film layer 140, the film layer 140 would not slump to cause a contact between the wires 160 and the encapsulant 150, so as to avoid damage, shift, miscontact of the wires 160 which may influence the electrical transmission function thereof.

Referring to FIG. 3, the chip package structure 100C of FIG. 3 is similar to the chip package structure 100A of FIG. 1E, but a difference there between is that in the present embodiment, an upper surface 130a of the carrier 130 of the chip package structure 100C is exposed but not covered by the encapsulant 150, so as to effectively conduct the heat generated during the operation of the chip 120 to outside and maintain the performance of the chip 120. Namely, under such configuration, the chip package structure 100C may also have the same technical effects as that described in the aforementioned embodiment.

In summary, since the chip and the wires are entirely encapsulated by the film layer first, and then further covered by the encapsulant having the electro-magnetic shielding filler, the packaged chip not only can effectively block the influence of the EMI through the encapsulant, but can also prevent the electrical contact between the chip and the electro-magnetic shielding filler by encapsulating the chip through the film layer. In detail, the film layer is, for example, a film-over-wire (FOW), which presents a semi-solid gel state when the film layer encapsulates the chip and the wires, so that the film layer has no interference on the wires. Therefore, the wires may easily penetrate into the semi-solid gel state film layer without being interfered by the film layer, which may lead to breaking or damage the wires. Besides, the film layer provides a certain degree of support after entirely encapsulating the chip and the wires, and would not slump to cause a contact between the wires and the carrier or the encapsulant, so as to avoid damage, shift, miscontact of the wires which may influence the electrical transmission function thereof. As the encapsulant has the electro-magnetic shielding filler, false operation or malfunction of the chip due to the external EMI can be effectively avoided.

On the other hand, the electro-magnetic shielding filler in the encapsulant which is a conductive material generally has the heat conduction effect, or a heat dissipation filler made of other materials can also be added in the encapsulant. Therefore, the chip package structure of the invention not only has better anti-EMI ability, but can also effectively conduct the heat generated during the operation of the chip to outside, so as to maintain or improve the performance of the chip.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A chip package structure, comprising:
a substrate having an upper surface and a lower surface;
a chip mounted on the upper surface of the substrate;
a plurality of wires electrically connected to the chip and the substrate respectively;
a film layer disposed on the substrate in a covering and attaching manner, and the film layer entirely encapsulating the chip and the wires;
a carrier adhered on the film layer; and
an encapsulant disposed on the upper surface of the substrate, the encapsulant having an electro-magnetic shielding filler, wherein the encapsulant at least partially encapsulates the carrier and the film layer, and the encapsulant covers the chip and the wires.

2. The chip package structure as claimed in claim 1, wherein the carrier comprises a flexible insulating film or a metal plate.

3. The chip package structure as claimed in claim 1, further comprising a plurality of external terminals disposed on the lower surface of the substrate and electrically connected to the substrate.

4. The chip package structure as claimed in claim 1, wherein the film layer is a film-over-wire (FOW), and the film layer presents a semi-solid gel state when the film layer encapsulates the chip and the wires, such that the film layer has no interference on the wires.

5. The chip package structure as claimed in claim 1, wherein a material of the electro-magnetic shielding filler is selected from a group consisting of Ag, Fe, ferrite, Cu, Cu/Ni, Cu/Ag, Au, Al, Ni, brass, stainless steel, graphite, carbon black, carbon nanotube, carbon nanocapsule, carbon fiber, nickel-plated graphite, nickel-plated carbon fiber and copper/nickel-plated carbon fiber.

6. The chip package structure as claimed in claim 1, wherein the encapsulant further comprises a heat dissipation filler.

7. The chip package structure as claimed in claim 6, wherein a material of the heat dissipation filler is selected from a group consisting of Ag, Fe, ferrite, Cu, Cu/Ni, Cu/Ag, Au, Al, Ni, Mg, brass, stainless steel, graphite, carbon black, carbon nanotube, carbon nanocapsule, carbon fiber, nickel-plated graphite, nickel-plated carbon fiber, copper/nickel-plated carbon fiber, Al₂O₃, MgO, BeO, SiO₂, ZnO, NiO, Si₃N₄ and BN.

8. A manufacturing method of a chip package structure, comprising:
providing a substrate, wherein the substrate has an upper surface and a lower surface;
mounting a chip on the upper surface of the substrate;
forming a plurality of wires, wherein the wires are electrically connected to the chip and the substrate, respectively;
disposing a film layer on the substrate in a covering and attaching manner, wherein a carrier is adhered on the film layer, and the film layer entirely encapsulates the chip and the wires; and
forming an encapsulant on the upper surface of the substrate, the encapsulant having an electro-magnetic shielding filler, wherein the encapsulant at least partially encapsulates the carrier and the film layer and the encapsulant covers the chip and the wires.

9. The manufacturing method of the chip package structure as claimed in claim 8, wherein the carrier comprises a flexible insulating film or a metal plate.

10. The manufacturing method of the chip package structure as claimed in claim 8, wherein the film layer is a film-over-wire (FOW), and the film layer presents a semi-solid gel state when the film layer encapsulates the chip and the wires, such that the film layer has no interference on the wires.

11. The manufacturing method of the chip package structure as claimed in claim 8, wherein a material of the electro-magnetic shielding filler is selected from a group consisting of Ag, Fe, ferrite, Cu, Cu/Ni, Cu/Ag, Au, Al, Ni, brass, stainless steel, graphite, carbon black, carbon nanotube, carbon nanocapsule, carbon fiber, nickel-plated graphite, nickel-plated carbon fiber and copper/nickel-plated carbon fiber.

12. The manufacturing method of the chip package structure as claimed in claim 8, wherein the encapsulant further comprises a heat dissipation filler.

13. The manufacturing method of the chip package structure as claimed in claim 12, wherein a material of the heat dissipation filler is selected from a group consisting of Ag, Fe, ferrite, Cu, Cu/Ni, Cu/Ag, Au, Al, Ni, Mg, brass, stainless steel, graphite, carbon black, carbon nanotube, carbon nanocapsule, carbon fiber, nickel-plated graphite, nickel-plated carbon fiber, copper/nickel-plated carbon fiber, Al₂O₃, MgO, BeO, SiO₂, ZnO, NiO, AlN, Si₃N₄ and BN.
